(19) United States
(12) Patent Application Publication
(10) Pub. No.: US 2008/0048649 A1
(43) Pub. Date: Feb. 28, 2008

(54) Thin input device and mobile terminal equipped with the same

(75) Inventors: Min Woong Choi, Gyunggi-do (KR); Ho Chul Joung, Gyunggi-do (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRO-MECHANICS CO, LTD, Suwon (KR)

(21) Appl. No.: 11/826,663

(22) Filed: Jul. 17, 2007

(30) Foreign Application Priority Data
Jul. 21, 2006 (KR) 10-2006-0068631

(51) Int. Cl. H01L 43/06

(52) U.S. Cl. 324/207.2

(57) ABSTRACT

Disclosed herein is a thin input device. The thin input device includes a manipulation means, a displacement detection means, and a housing. The manipulation means is capable of being displaced in any direction. The displacement detection means is electrically connected to an external device and detects the displacement of the manipulation means. The housing detachably is mounted on the support element of the external device and contains the manipulation means.

### CROSS REFERENCE TO RELATED APPLICATION

This application claims the benefit of Korean Patent Application No. 10-2006-0068631, filed on Jul. 21, 2006, entitled “Thin Input Device and Handset Provided with the Same,” which is hereby incorporated by reference in its entirety into this application.

### BACKGROUND OF THE INVENTION

1. Field of the Invention

The present invention relates generally to an input device and, more particularly, to an input device that is thin and allows the parts thereof to be separately and easily repaired or replaced in the event of the failure of the parts, such as a manipulation element that is frequently used, and a terminal equipped with the input device.

2. Description of the Related Art

Input devices are auxiliary devices that are installed in various mobile terminals, such as a mobile phone and a remote control, which are widely used in homes, and that are used to receive input commands from users. In line with the reduction in the size and thickness of mobile terminals, the size and thickness of input devices have been reduced, and input devices have been developed to increase the ease of manipulation by users.

An example of a prior art input device is a “Terminal Equipped with Pointing Device,” which was disclosed in Japanese Unexamined Patent Publication No. 2005-107672 and is shown in FIG. 5.

As shown in FIG. 5, a prior art pointing device 22 includes a manipulation member 30 for securely accommodating a magnet 28, and a support member 32 for supporting the manipulation member 30 so that the manipulation member 30 can be displaced with respect to a circuit board 44. The magnet 28, the manipulation member 30 and the support member 30 constitute a manipulation assembly 34. The support member 36 is fastened to the central depression bottom 30a of the manipulation member 30, and horizontally moves while sliding along the support surface 32a of the support member 32 in any direction.

The manipulation member 30 has elasticity, so that it can be easily deformed on the support member 32 to perform displacement manipulation. The manipulation member 30 integrally includes a touch manipulation part 38 having a central depression bottom(30a), an elastic spring part 40 extending outward from the touch manipulation part 38, and a connection part(42) spanning from the elastic spring part 40 to the support member 32. The elastic spring part 40 is arranged coaxially with the support member 32, and has a high and flat cone or dome shape.

The support member 32 has a flat support surface 32a that supports the support member 36 so that the support member 36 freely slides in a horizontal direction. A cylindrical wall 44 for defining the range of the horizontal movement of the support member 36 is formed to protrude. The central axis of the cylindrical wall 44 passing through the center of the support surface 32a constitutes the central axis P of the pointing device 22 and, at the same time, defines the location of the origin of the horizontal movement of the support member 36 on the support surface 32a.

The connection part 42 of the manipulation member 30 is attached within an annular groove defined between the cylindrical wall 44 of the support member 32 and the outer wall 46. A cover plate 48 having an central opening 48a is mounted on the support member 32 so that the cover plate 48 substantially covers the circumferential regions of the manipulation member 30 and the support member 32 where they are engaged with each other. The cover plate 48 holds the manipulation member 30 and the support member 32 in an appropriately assembled state, with the support member 36 fastened to the manipulation member 30 being placed on the support surface 32a of the support member 32 so that the support member 36 can freely slide on the support surface 32a.

The manipulation assembly 34 is fastened to the upper box 20 or the circuit board 14 using a method, such as bonding or welding, with the touch manipulation part 38 of the manipulation member 30 being inserted through the opening 24 of the upper box 20. Four magneto-electric transducers 26 fixedly mounted on the back of the circuit board 14 are distributed and arranged around the central axis P of the pointing device 22 at regular intervals.

However, in the prior art pointing device having the above-described construction, the manipulation assembly 34 is fastened to the upper box 20 or circuit board 14 using the method, such as bonding or welding, so that a bonding means or a welding means is required for the fastening, and so that the assembly 34 cannot be detached once it has been fastened. Accordingly, a problem arises in that the assembly 34, together with the circuit board 14, must be replaced in the event that the assembly 34 is required to be replaced due to failure or the like.

### SUMMARY OF THE INVENTION

Accordingly, the present invention has been made keeping in mind the above problems occurring in the prior art, and the present invention is intended to provide a thin input device, in which a housing for containing a manipulation assembly is detachably and directly mounted on the main circuit board of a terminal, so that the thickness of parts can be reduced and the parts can be separately replaced, and a mobile terminal equipped with the thin input device.

The present invention provides a thin input device, including a manipulation means capable of being displaced in any direction; a displacement detection means electrically connected to an external device, and configured to detect the displacement of the manipulation means; and a housing detachably mounted on the support element of the external device and configured to contain the manipulation means.

The input device according to the invention is characterized that the external device is a terminal, and the support element is a main circuit board mounted in the terminal.

The manipulation means has magnetism, and the displacement detection means detects the displacement of the manipulation means by detecting variation in intensity of magnetic force resulting from the displacement of the manipulation means.

The displacement detection means includes a plurality of Hall sensors that are responsive to magnetic force.

Additionally, the present invention provides a thin input device, including a manipulation element capable of being displaced in an any direction; a magnetic element having a displacement identical to a displacement of the manipulation element; a magnetic sensor mounted on a main circuit board of a terminal, and configured to detect the displacement of the manipulation element by detecting variation in intensity of magnetic force resulting from the displacement of the magnetic element; and a housing detachably mounted on the main circuit board, and configured to contain the manipulation element and the magnetic element.

The thin input device further includes an elastic element that is fastened to the manipulation element and returns the manipulation element to an original position thereof.

The housing has an opening that exposes a contact part of the manipulation element to the outside and that provides a displacement region for the contact part.

The housing has an accommodation cavity for accommodating the manipulation element and the magnetic element, and a circumferential wall for defining the accommodation cavity.

The housing has a plurality of coupling protrusions to be inserted into and engaged with coupling holes formed in the main circuit board, the coupling protrusions being formed at a free end of the circumferential wall at regular intervals.

The coupling protrusions have hook-shaped ends that face outward.

Additionally, the present invention provides a mobile terminal, including the above-mentioned input device; and a main circuit board on one surface of which the housing is detachably mounted and on a remaining surface of which the displacement detection means or the magnetic sensor is mounted.

### BRIEF DESCRIPTION OF THE DRAWINGS

The above and other objects, features and advantages of the present invention will be more clearly understood from the following detailed description, taken in conjunction with the accompanying drawings, in which:

FIG. 1 is a schematic exploded perspective view showing a thin input device according to a preferred embodiment of the present invention;

FIG. 2 is a schematic sectional view showing the input device of FIG. 1;

FIG. 3 is a schematic diagram showing the movement of a magnetic element resulting from the movement of the manipulation unit of FIG. 1;

FIG. 4 is a schematic exploded perspective diagram showing part of a terminal in which the input device of FIG. 1 is installed; and

FIG. 5 is a schematic sectional diagram showing a prior art input device.

### DESCRIPTION OF THE PREFERRED EMBODIMENTS

Reference now should be made to the drawings, in which the same reference numerals are used throughout the different drawings to designate the same or similar components.

An input device and a mobile terminal equipped with the input device according to a preferred embodiment of the present invention will be described in detail below with reference to the accompanying drawings.

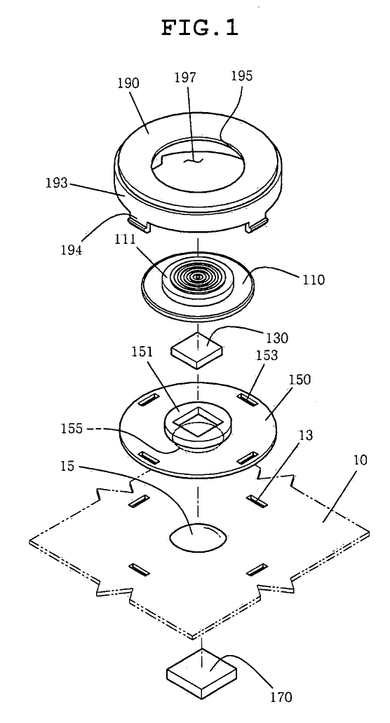

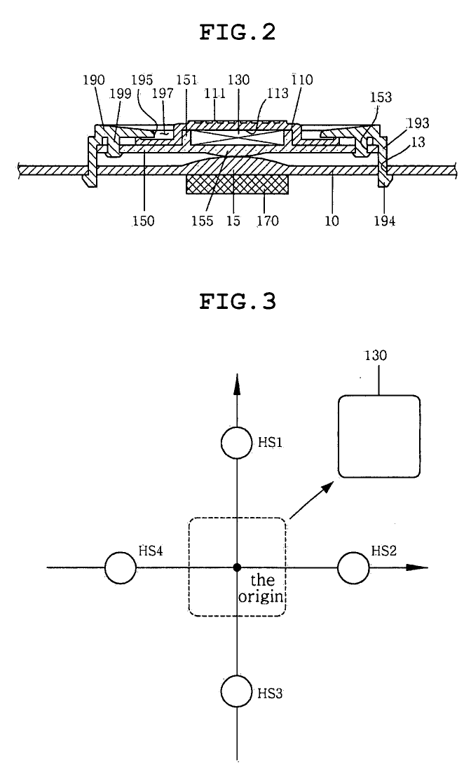

First, with reference to FIGS. 1 and 2, the thin input device 100 according to the embodiment of the present invention will be described. FIG. 1 is a schematic exploded perspective view showing the thin input device 100 according to the embodiment, and FIG. 2 is a schematic sectional view showing the input device of FIG. 1.

As shown in FIGS. 1 and 2, the input device 100 according to the embodiment includes a manipulation element 110, a magnetic element 130, an elastic element 150, a magnetic sensor 170, and a housing 190.

The manipulation element 110 is used by a user to input desired signals to the input device 100 through manipulation in specific directions. A contact part 111, which actually comes into contact with the user's finger, is provided at the center of the manipulation element 110, and an accommodation depression 113, which accommodates a magnetic element mount 151, on which the magnetic element 130 is mounted, is provided in the back of the manipulation element 110.

The contact part 111 is made of lightweight aluminum having a predetermined strength, and is provided with a plurality of small annular protrusions that increase the area of contact with the user's finger. Alternatively, the contact part 111 may be at least partially coated with material that has an excellent contact property.

The magnetic element 130 is a detection means for transmitting a signal about the displacement of the magnetic element 130 or manipulation element 110 to Hall sensors (HS1, HS2, HS3, and HS4 of FIG. 3) by applying magnetic force to the Hall sensors contained in the magnetic sensor 170. The magnetic element 130 is accommodated in and mounted on the magnetic element mount 151 formed in the elastic element 150. In an embodiment, a permanent magnet may be used as the magnetic element 130.

The elastic element 150 is used to restore the manipulation element 110, which has been displaced in a specific direction, to its origin, and is made of material having excellent rigidity as well as excellent elasticity. However, any means for generating restoring force, other than the element made of rubber, may be used.

Furthermore, the magnetic element mount 151, in and on which the magnetic element 130 is accommodated and mounted, protrudes somewhat from the center of the elastic element 150, and a plurality of coupling holes 153 (in the present embodiment, four coupling holes), which will be engaged with coupling protrusions 197, is arranged along the area of the elastic element 130 near the circumference of the elastic element 150. In an embodiment, the coupling holes 153 are formed to have a diameter identical to or somewhat smaller than that of the coupling protrusions 197, so as to be tightly engaged with the coupling protrusions 197.

Furthermore, a protrusion 155, which is somewhat inclined and is disposed coaxially with the manipulation element 110, is provided at the center of the back of the elastic element 150. The protrusion 155 comes into contact with an operation switch 15, such as a metal dome switch, which is provided on a circuit board 10 coaxially with the manipulation element 110.

The manipulation element 110, the magnetic element 130 and the elastic element 150 may be constructed in the form of a single assembly, which may be called a manipulation assembly.

The magnetic sensor 170 is a displacement detection means for detecting the displacement of the magnetic element 130 or manipulation element 110, and is disposed on the back of the circuit board 10 coaxially with the magnetic element 130.

The magnetic sensor 170 contains a plurality of Hall sensors, in the present embodiment, 4 Hall sensors (HS1, HS2, HS3 and HS4 of FIG. 3), which detect variation in the intensity of magnetic force resulting from the displacement of the magnetic element 130, and which are disposed at equal distances from a central axis.

The housing 190 is a means for containing the manipulation assembly made up of the manipulation element 110, the magnetic element 130 and the elastic element 150, and protecting it from the outside, and is constructed in the form of a container having an accommodation depression 191 and a side wall 193. A plurality of coupling protrusions 194, in the present embodiment, four coupling protrusions, which will be engaged with the circuit board 10, is provided on the side wall 193 at regular intervals. The ends of the coupling protrusions 194 have the shape of a hook that faces outward.

An opening 195, through which some of the manipulation element 110, including the contact part 111, is exposed to the outside, is formed in the center of the housing 190. The opening 195 defines the manipulation element 110, particularly the region of the displacement of the contact part 111. The coupling protrusions 199, which are engaged with the elastic element 150, are provided between the opening 195 and the side wall 193.

The coupling protrusions 199 are configured such that the combination of the elastic element 150 is easy and the separation thereof is difficult because they are formed to have a column shape and free ends inclined and somewhat wider than column parts.

A main circuit board installed in a mobile terminal in which the input device 100 is installed may be used as the circuit board 10. As described above, the metal dome switch 15 is disposed on the upper surface of the elastic element 150 coaxially with the manipulation element 110, and the magnetic sensor 170 is disposed on the lower surface of the elastic element 150 coaxially with the manipulation element 110. A plurality of coupling holes 13, in the present embodiment, four coupling holes 13, into which coupling protrusions 194 are inserted, is provided at locations corresponding to those of the coupling protrusions 194 of the housing 190.

In the above-described input device 100, when the contact part 111 or manipulation element 110 is manipulated in a specific direction by a user, the magnetic element 130 contained in the manipulation element 110 is manipulated in the same way, and the location of the magnetic element 130 is changed. Information about the displacement of the magnetic element 130 is transmitted to the Hall sensors provided in the magnetic sensor 170, and the displacement of the magnetic element 130 or manipulation element 110 is detected. Furthermore, the information about the displacement is transmitted through the circuit board 10, and is displayed on the display unit of the terminal by a display means, such as a cursor.

FIG. 3 schematically shows the displacement of the magnetic unit resulting from the manipulation of the manipulation element 110. Here, a point indicated as an origin is a location that coincides with the central axis of the manipulation element 110. FIG. 3 shows an example in which the magnetic element 130, which was located at the origin and is indicated by the dotted line, has been moved in the upper left direction. Furthermore, although, for ease of description, the Hall sensors HS1, HS2, HS3 and HS4 have been illustrated as being somewhat far away from the magnetic element 130, the Hall sensors are actually disposed in the same arrangement within an area corresponding to the size of the magnetic element 130.

When the magnetic element 130 is located at the origin, as indicated by the dotted line, all four of the Hall sensors detect magnetic force having the same magnitude. In contrast, when the magnetic element 130 is located in the upper right, as indicated by the solid line, the Hall sensors HS1 and HS2 closer to the magnetic element 130 detect stronger magnetic force, while the Hall sensors HS3 and HS4 further from the magnetic element 130 detect weaker magnetic force. The intensity of magnetic force detected by the Hall sensors HS1, HS2, HS3 and HS4 varies with the displacement of the magnetic element 130, and the Hall sensors HS1, HS2, HS3 and HS4 detect the displacement of the magnetic element 130 based on the variation in the intensity of magnetic force detected as described above. Through the above-described process, the displacement of the manipulation element 110 can be detected.

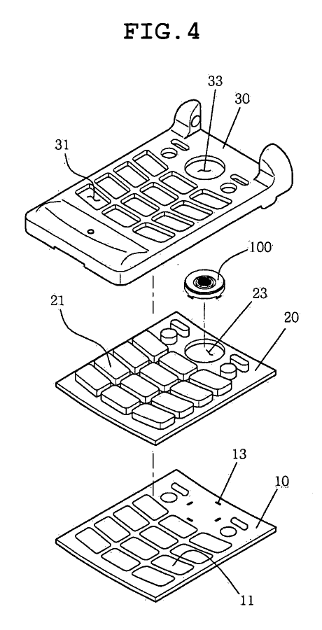

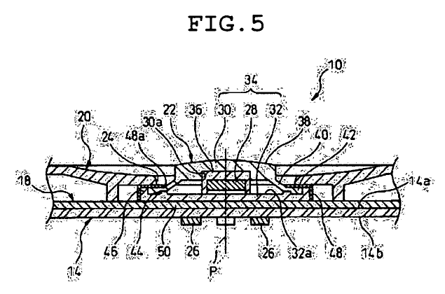

The installation of the above-described input device 100 in the mobile terminal is illustrated in FIG. 4 as an example.

The mobile terminal includes the circuit board 10, the key panel 20, and the case 30, separated into upper and lower parts.

The circuit board 10 is provided with a plurality of switches 11, which are main functional elements, on the front thereof. Although not shown in the drawing, a plurality of electronic parts, including the magnetic sensor (170 of FIG. 1), is mounted on the back of the circuit board 10. As described above, coupling holes 13 engaged with the input device 100 are formed in the center portion of the upper part of the circuit board 10. The metal dome switch 15, which is an operation switch, is disposed coaxially with the manipulation element 110.

The key panel 20 is a thin member made of elastic material, such as synthetic rubber. A plurality of elastically deformable pressing elements 21 protrudes from the upper surface of the key panel 20 at locations corresponding to the locations of the switches 11 of the circuit board 10. The pressing elements 21 are arranged to substantially overlap respective switches 11 of the circuit board 10. An opening 23, through which the input device 100 passes, is formed in the upper center of the key panel 20.

The case 30 is a thin box-shaped member, which is a resin molded product. In this drawing, only the upper one of upper and lower cases is illustrated. A plurality of through holes 31, through which the pressing elements 21 pass and are exposed, is formed in the case 30 at corresponding locations. An opening 33, through which the input device 100 pass and are exposed, is formed in the upper center of the case 30 at a location corresponding to that of the opening 23.

According to the input device of the present invention, the housing in which the manipulation assembly is contained is directly mounted on the main circuit board of the terminal, so that the thickness of the terminal can be reduced, thus making it possible to realize thin or slim terminals.

Furthermore, since the housing is mounted on the circuit board by inserting the hook-shaped coupling protrusions into the circuit board, the housing can be freely separated from the circuit board, therefore parts can be separately and freely replaced.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

What is claimed is:

1. A thin input device, comprising:
manipulation means capable of being displaced in any direction;
displacement detection means electrically connected to an external device, and configured to detect displacement of the manipulation means; and
a housing detachably mounted on a support element of the external device, and configured to contain the manipulation means.

2. The thin input device as set forth in claim 1, wherein the external device is a terminal, and the support element is a main circuit board mounted in the terminal.

3. The thin input device as set forth in claim 2, wherein the manipulation means has magnetism, and the displacement detection means detects the displacement of the manipulation means by detecting variation in intensity of magnetic force resulting from the displacement of the manipulation means.

4. The thin input device as set forth in claim 3, wherein the displacement detection means comprises a plurality of Hall sensors that are responsive to magnetic force.

5. A thin input device, comprising:
a manipulation element capable of being displaced in an any direction;
a magnetic element having a displacement identical to a displacement of the manipulation element;
a magnetic sensor mounted on a main circuit board of a terminal, and configured to detect the displacement of the manipulation element by detecting variation in intensity of magnetic force resulting from the displacement of the magnetic element; and
a housing detachably mounted on the main circuit board, and configured to contain the manipulation element and the magnetic element.

6. The thin input device as set forth in claim 5, further comprising an elastic element that is fastened to the manipulation element and returns the manipulation element to an original location thereof.

7. The thin input device as set forth in claim 5, wherein the housing has an opening that exposes a contact part of the manipulation element to an outside and provides a displacement region for the contact part.

8. The thin input device as set forth in claim 6, wherein the housing has an opening that exposes a contact part of the manipulation element to an outside and provides a displacement region for the contact part.

9. The thin input device as set forth in claim 5, wherein the housing has an accommodation cavity for accommodating the manipulation element and the magnetic element, and a circumferential wall for defying the accommodation cavity.

10. The thin input device as set forth in claim 9, wherein the housing has a plurality of coupling protrusions to be inserted into and engaged with coupling holes formed in the main circuit board, the coupling protrusions being formed at a free end of the circumferential wall at regular intervals.

11. The thin input device as set forth in claim 10, wherein the coupling protrusions have hook-shaped ends that face outward.

12. The thin input device as set forth in claim 6, wherein the housing has an accommodation cavity for accommodating the manipulation element and the magnetic element, and a circumferential wall for defining the accommodation cavity.

13. The thin input device as set forth in claim 12, wherein the housing has a plurality of coupling protrusions to be inserted into and engaged with coupling holes formed in the main circuit board, the coupling protrusions being formed at a free end of the circumferential wall at regular intervals.

14. The thin input device as set forth in claim 13, wherein the coupling protrusions have hook-shaped ends that face outward.

15. A mobile terminal, comprising:
the input device which is set forth in claim 1; and
a main circuit board on one surface of which the housing is detachably mounted and on a remaining surface of which the displacement detection means or the magnetic sensor is mounted.

16. A mobile terminal, comprising:
the input device which is set forth in claim 5; and
a main circuit board on one surface of which the housing is detachably mounted and on a remaining surface of which the displacement detection means or the magnetic sensor is mounted.
